(19) United States
(12) Patent Application Publication
(10) Pub. No.: US 2015/0170923 A1
(43) Pub. Date: Jun. 18, 2015

(54) Feature Size Reduction in Semiconductor Devices by Selective Wet Etching

(71) Applicant: Intermolecular, Inc., San Jose, CA (US)

(72) Inventors: Federico Nardi, Palo Alto, CA (US); Randall J. Higuchi, San Jose, CA (US); Robert A. Huertas, Hollister, CA (US); Yun Wang, San Jose, CA (US)

(73) Assignee: Intermolecular, Inc., San Jose, CA (US)

(21) Appl. No.: 14/133,546

(22) Filed: Dec. 18, 2013

(51) Int. Cl. H01L 21/306

(52) U.S. Cl. CPC H01L 21/306

(57) ABSTRACT

Selective wet etching is used to produce feature sizes of reduced width in semiconductor devices. An initial patterning step (e.g., photolithography) forms a pillar of an initial width from at least a selected first layer and an overlayer. A wet etchant that is selective to the selected layer undercuts the sidewalls of the selected layer to a smaller width while leaving at least part of the overlayer in place to protect the top surface of the selected layer. The selected layer becomes a narrow “stem” within the pillar, and may have dimensions below the resolution limit of the technique used for the initial patterning. For some devices, voids may be intentionally left in a fill layer around the stem for electrical or thermal insulation.

### BACKGROUND

Related fields include semiconductor device fabrication, particularly wet etching processes.

Advanced semiconductor devices require smaller feature sizes; for dense packing of components, for lower operating power, or for other reasons.

For example, if a device operates based on a change in material structure induced by heat or electric-field strength, less energy is needed to operate the device if the heat or electric field is confined to a smaller active volume. There is often a limit to how far the thickness of a layer can be reduced because of unwanted electron tunneling, agglomeration of the thin layer after annealing, or some other consideration. In those cases, the only way to further reduce the active volume is to reduce its lateral extent.

In addition, when the device size begins to affect the physical behavior of the materials, it becomes necessary to test candidate materials “at-dimension,” i. e., to fabricate and characterize material samples with the same dimensions as the corresponding features in the planned devices, because the results from larger samples might not accurately predict the behavior of the smaller device features.

The lateral extent of a fabricated feature may be limited by the technology used to pattern the material. For example, conventional UV photolithography at a wavelength of 248 nm (e.g., from a KrF excimer laser) can only produce features with a lateral extent of about 20 nm or greater. Smaller features can be made by advanced techniques such as 193 nm immersion lithography, double patterning, extreme UV lithography, or electron beam lithography. However, these techniques can be time-consuming and the equipment required is very expensive.

Therefore, a need exists for simpler, more cost-effective way to produce features with smaller lateral extent for semiconductor devices and test structures.

### SUMMARY

The following summary presents some concepts in a simplified form as an introduction to the detailed description that follows. It does not necessarily identify key or critical elements and is not intended to reflect a scope of invention.

Methods that include selective wet etching after conventional patterning may produce features that are smaller in lateral extent than the resolution limit of the conventional patterning technique. A substrate may be coated with a film stack that includes at least one selected layer (that is, selected to make the reduced-width feature) and at least one overlayer over the selected layer. A conventional patterning technique, such as 248 nm photolithography or non-selective etching through a mask, is used to form a pillar of an initial lateral size from at least the overlayer and the selected layer. The pillar is then exposed to a wet etchant that selectively undercuts the sidewalls of the selected layer to a reduced width, but does not etch the overlayer enough to expose the top surface of the selected layer. The selected layer thus becomes a narrowed “stem” within the pillar.

The etchant chemistry, the process conditions, and the composition and thickness of the overlayer are all parameters that can be chosen to undercut the selected layer to a stem without unwanted effects on the substrate or on other layers that may be present in the pillar. The overlayer may also be partially etched by the wet etchant, or it may remain substantially intact after exposure to the wet etchant. Herein, “substantially intact” means “losing less than 10% of its extent in any dimension.” The substrate may also remain substantially intact after exposure to the wet etchant.

After one or more reduced-width stems are formed from selected layers in the pillar, a fill is formed around (and optionally over) the pillar. The fill may be, for example, an electrical and/or thermal insulator. The fill may include multiple layers. The fill may conformally contact the sidewalls of the stem, or may be formed to intentionally leave one or more voids near the sidewalls of the stem to take advantage of the insulating properties of empty space (vacuum, trapped gas, or air).

The overlayer may be a sacrificial layer that is removed later, or the overlayer may also become part of the device. In some embodiments, a sacrificial overlayer may be removed before forming the fill layer, by a wet etch selective to the overlayer or by an anisotropic etch that removes the overlayer without impacting the stem sidewalls. Alternatively, a sacrificial overlayer may be removed after the fill layer is formed. A planarization technique such as chemical-mechanical polishing (CMP) may remove the top portion of the fill over the overlayer, and then continue to remove both fill and overlayer until a top surface of the stem is exposed.

With available selective wet etchants, the selected layer may be a conductive layer, a dielectric layer, a semiconducting layer, or a layer with switchable electrical properties. Examples of selected layers that may be made into reduced-width stems include resistors, capacitor electrodes, switchable layers in nonvolatile memory, and dummy gates in gate-last logic fabrication.

### BRIEF DESCRIPTION OF DRAWINGS

The accompanying drawings may illustrate examples of concepts, embodiments, or results. They do not define or limit the scope of invention. They are not drawn to any absolute or relative scale. In some cases, identical or similar reference numbers may be used for identical or similar features in multiple drawings.

FIGS. 1A-1D conceptually illustrate formation of a reduced-width “stem” from a selected layer of a pillar.

FIGS. 2A-2D illustrate some examples with a functional overlayer that is left above the stem for subsequent processes.

FIG. 3A-3C illustrate some examples with a sacrificial overlayer that is removed at some point after creating the stem.

FIG. 4 is a flowchart of a process for forming pillars having one or more stem layers with reduced width.

FIG. 5 conceptually illustrates a reduced-width series resistor in a device stack.

FIG. 6 conceptually illustrates a reduced-width switching layer in a non-volatile memory cell.

FIGS. 7A-7B conceptually illustrate test structures with reduced effective width for screening candidate capacitor materials.

FIGS. 8A-8E conceptually illustrate a “gate-last” transistor fabrication with a reduced-width gate.

### DETAILED DESCRIPTION OF EXAMPLE EMBODIMENTS

A detailed description of one or more example embodiments is provided below. To avoid unnecessarily obscuring the description, some technical material known in the related fields is not described in detail. Semiconductor fabrication generally requires many other processes before and after those described; this description omits steps that are irrelevant to, or that may be performed independently of, the described processes.

Unless the text or context clearly dictates otherwise: (1) By default, singular articles “a,” “an,” and “the” (or the absence of an article) may encompass plural variations; for example, “a layer” may mean “one or more layers.” (2) “Or” in a list of multiple items means that any, all, or any combination of less than all the items in the list may be used in the invention. (3) Where a range of values is provided, each intervening value is encompassed within the invention. (4) “About” or “approximately” contemplates up to 10% variation. “Substantially” contemplates up to 5% variation.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” allows for optional intervening elements.

“Substrate,” as used herein, may mean any workpiece on which formation or treatment of material layers is desired. Substrates may include, without limitation, silicon, silica, sapphire, zinc oxide, SiC, AlN, GaN, Spinel, coated silicon, silicon on oxide, silicon carbide on oxide, glass, gallium nitride, indium nitride and aluminum nitride, and combinations (or alloys) thereof. The term “substrate” or “wafer” may be used interchangeably herein. Semiconductor wafer shapes and sizes can vary and include commonly used round wafers of 50 mm, 100 mm, 150 mm, 200 mm, 300 mm, or 450 mm in diameter. As used herein, “etch” shall mean any chemical removal of solid material, whether or not the material is being removed in any specific pattern. “Conformal” as used herein shall mean “at least 75% conformal.”

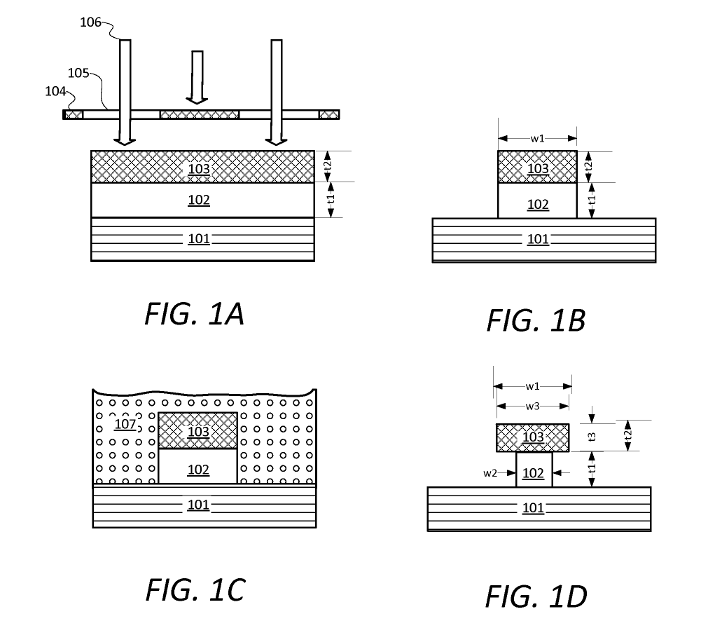

FIGS. 1A-1D conceptually illustrate formation of a reduced-width “stem” from a selected layer of a pillar. In FIG. 1A, a substrate 101 includes at least selected layer 102 and overlayer 103 formed over (that is, farther from substrate 101 than) selected layer 102. Selected layer 102 has thickness t₁ and overlayer 103 has thickness t₂. Depending on the device, the thicknesses may be anywhere from a few tenths of a nanometer to several micrometers. In some embodiments, other layers may also be present. Each of the layers discussed herein and used in the described devices may be formed using any suitable technique such as physical vapor deposition (PVD), atomic layer deposition (ALD), plasma enhanced atomic layer deposition (PE-ALD), atomic vapor deposition (AVD), ultraviolet assisted atomic layer deposition (UV-ALD), chemical vapor deposition (CVD), plasma enhanced chemical vapor deposition (PECVD) or evaporation. The examples may discuss one or more preferred methods for specific materials or devices, but the teaching is not limited by the technology used to form any of the layers.

Initially, selected layer 102 and overlayer 103 are conventionally patterned, for example by patterning agent 106 through window, aperture, or other transmissive region 105 in mask 104. Any suitable conventional patterning technique may be used. Patterning agent 106 may be, for example, light, plasma, or a non-selective wet etchant that etches both selected layer 102 and overlayer 103. Mask 104 may be a contact mask, a photomask, a projected mask, a shadow mask, a deposited hard mask, or anything suitable for forming patterns in selected layer 102 and overlayer 103 using patterning agent 106.

FIG. 1B shows the effects of the initial conventional patterning: unremoved portions of selected layer 102 and overlayer 103 form a pillar of width w₁ in the x-direction and height (t₁+t₂) in the y-direction. These are cross-sectional views in an x-y plane; the pillar may have the same width or a different width in the z-direction “into” or “out of” the page. Width w₁ may be, for example, between 20 and 500 nm.

FIG. 1C shows substrate 101 with the pillar including selected layer 102 and overlayer 103 being exposed to a selective wet etchant 107. The exposure may be done by immersion in a bath of selective wet etchant 107, or by spraying or flowing selective wet etchant 107 onto substrate 101. Optionally, substrate 101 or selective wet etchant 107 may be spun or vibrated (e.g., by ultrasonic or megasonic vibration) during the exposure. Selective wet etchant 107 is chosen to etch the material of selected layer 102 faster than it etches the material of overlayer 103 or exposed materials on substrate 101.

FIG. 1D shows substrate 101 with the pillar including selected layer 102 and overlayer 103 after being exposed to the selective wet etchant 107. Selective wet etchant 107 etched the sidewalls of selected layer 102 to a reduced width w₂ that is less than the original pillar width w₁, but preserved its thickness t₁ because its top and bottom surfaces were sealed against neighboring layers. Selected layer 102 is now a narrowed “stem” within the pillar. The stem width w₂ may, in some embodiments, be less than 20 nm or even less than 10 nm. In some embodiments, overlayer 103 may be partially etched to a width w₃ that is less than w₁ (but greater than or equal to w₂) and a thickness t₃ that is less than t₂. In some embodiments, overlayer 103 may be left substantially intact, so that w₃>=90% of w₁ and t₃>=90% of t₂. In some embodiments, exposed layers on substrate 101, outside the pillar, may also be left substantially intact.

A variety of selective wet etchant formulations and accompanying process parameters (e.g., temperature and concentration) are known in the semiconductor art. Some are described in co-owned U.S. Pat. No. 8,575,016 (filed 19 Oct. 2012 with priority to 20 May 2011) and co-owned U.S. patent application Ser. No. 13/305,949 (filed 29 Nov. 2011), Ser. No. 13/541,397 (filed 3 Jul. 2012), Ser. No. 13/725,358 (filed 21 Dec. 2012), Ser. No. 13/726,760 (filed 26 Dec. 2012), Ser. No. 13/727,776 (filed 27 Dec. 2012), Ser. No. 13/857,696 (filed 5 Apr. 2013) and Ser. No. 13/913,672 (filed 10 Jun. 2013), all of which are incorporated by reference herein for all purposes. For example, metal nitrides such as titanium nitride can be selectively etched with NH₄OH—H₂O₂ solutions or NH₄—H₂O₂ solutions or low-temperature phosphoric acid solutions or H₂SO₄—H₂O₂—HF solutions; metal oxides such as hafnium oxide and zirconium oxide can be selectively etched with HF—HCl solutions or HF solutions diluted with water or ethylene glycol; silicon dioxide and polysilicon can be selectively etched with HF—H₂O₂ solutions or HF-ozonated water solutions; metals such as copper and tantalum can be selectively etched with aqueous HF—HCl solutions.

To choose a selective wet etchant, one needs to know its etch rates E_{SL} for the selected layer material, E_{OL} for the overlayer material, and the set {E_{SUB}} for any materials that will be exposed on the substrate. In general, E_{SL} may be greater than or equal to E_{OL} and greater than any element of {E_{SUB}}. Depending on how intact the overlayer and substrate must remain while removing the desired amount of material from the selected layer, there, may be a minimum difference between, or a minimum ratio of, the etch rates.

In a simple example, suppose there is only one selected layer and only one material that will be exposed on the substrate after the pillar is formed. Suppose that the starting width of the pillar, w₁, is 20 nm and the desired stem width, w₂, is 10 nm. That means 5 nm of the selected material needs to be removed from each sidewall of the selected layer of the pillar. Suppose Etchant A has E_{SL}=5 nm/min, E_{OL}=2 nm/min, and E_{SUB}=0.1 nm/min. Exposure to Etchant A for 1 min will reduce the width of the selected layer from w₁=20 nm to w₂=10 nm (by taking 5 nm from each of two opposing sidewalls). It will also reduce the width of the overlayer from w₁=20 nm to w₂=16 nm (by taking 2 nm from each of two opposing sidewalls). It will also reduce the height of the overlayer above the stem by 2 nm (and may also remove some material from the edges of the bottom of the overlayer as it becomes exposed by the faster thinning of the selected layer). It will also remove 0.1 nm from the exposed surface of the substrate, which may or may not be significant, depending on the overall thickness and the intended function of that layer.

Most efficiently, the overlayer may also be part of the device (e.g., a conductive overlayer may be operable as a contact or electrode; an insulating overlayer may be operable as a barrier or buffer) and a wet etchant is found that is sufficiently selective to the selected layer and sufficiently unselective to both the substrate material and the overlayer material. If that is not feasible, the overlayer can be a sacrificial layer that only needs to temporarily protect the top surface of the selected layer during the selective wet etch.

In some embodiments, the overlayer, sacrificial or not, may be formed from the same material as the substrate layer under the bottom of the pillar. This eliminates one of the constraints on the selective wet etchant.

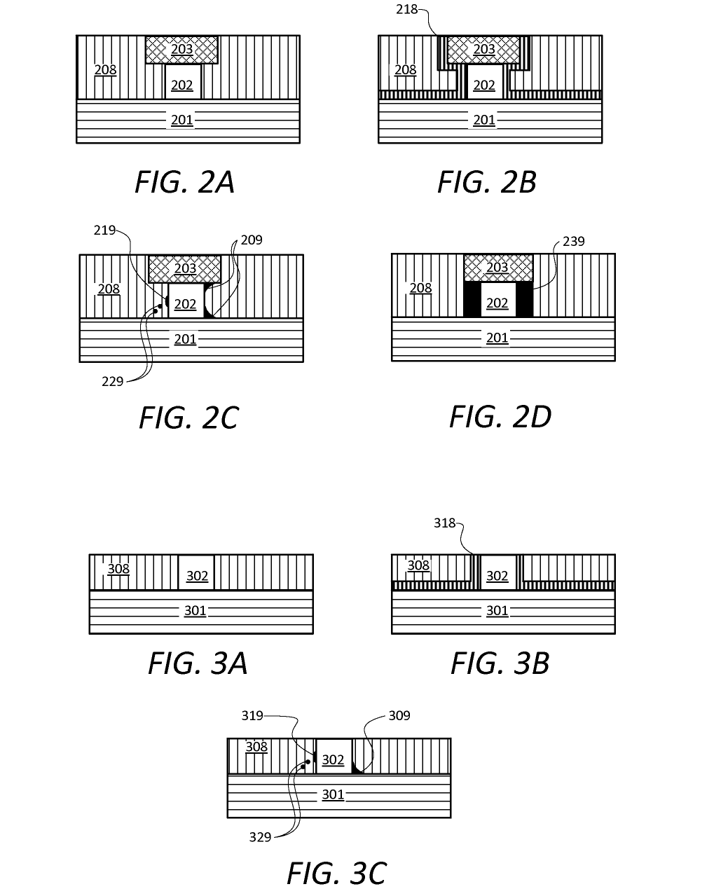

FIGS. 2A-2D illustrate some examples with a functional overlayer that is left above the stem for subsequent processes. In these figures, the fill (e.g., an interlayer dielectric, or, if appropriate, for the device, a metal fill) has been formed over and around substrate 201 and the pillar formed by stem 202 and overlayer 203, then planarized (e/g., by CMP or laser planarization) down to or past the original top surface of overlayer 203, still leaving at least a portion of overlayer 203 in place. Alternatively, a via, trench, or other opening may be formed in the fill layer to expose the overlayer. Embodiments that are combinations or hybrids of these examples may also fall within the scope.

In FIG. 2A, fill 208 fills in completely around the pillar, not leaving any gaps around stem 202. For example, fill 208 may be deposited by ALD, and material from the precursors adsorbs to all the exposed surfaces, including the sidewalls of stem 202 and the exposed part of the bottom surface of overlayer 203. As another example, fill 208 may be deposited by a wet process using one or more fluids capable of wetting the sidewalls of stem 202.

IN FIG. 2B, a conformal liner layer 218 is formed (for example by ALD or a sufficiently non-viscous wet process) on substrate 201 and around the pillar formed by stem 202 and overlayer 203 before fill 208 is formed. In some embodiments, this may allow a process with less-complete step coverage to be used for fill 208. In some embodiments, liner layer 218 may be a diffusion barrier or other functional layer used in the device. Multiple liner layers may be used.

In FIG. 2C, fill layer 208 has one or more voids, with diameters smaller than the stem height, in the space around stem 202 between the bottom of upper neighboring layer 203 and the top of lower neighboring layer 201. The voids may be incompletely filled corners 209, interfacial voids 219, or bulk voids 229. Although voids can be detrimental to some types of structures, in others they may enhance the ability of fill 208 to electrically or thermally insulate stem 202.

In FIG. 2D, voids 239 extend along substantially the entire thickness (e.g., >95% of the thickness) of stem 202. To produce this, fill 208 may be deposited by a non-conformal method such as PVD or a wet deposition using liquids too viscous to wet into the gap around stem 202. This confers the thermal, electrical, and diffusion-barrier properties of empty space around stem 202. In some embodiments, an inert process gas such as argon (Ar) may be trapped in voids 239 (or in voids 209, 219 or 229 in FIG. 2C).

FIG. 3A-3C illustrate some examples with a sacrificial overlayer that is removed at some point after creating the stem. This can be done in a number of ways. The planarization discussed with reference to FIGS. 2A-2D may simply continue until the entire overlayer is removed and stem 302 is exposed. Alternatively, a via, trench, or other opening may be formed in the fill layer to and/or any remaining portion of the overlayer to expose the selected layer. Alternatively, after creating stem 302, the overlayer may be etched away with another selective wet etchant that etches it much faster than it etches stem 302 or substrate 301. Alternatively, after creating stem 302, the overlayer may be etched away with a non-selective dry etchant if some loss from substrate 301 can be tolerated. Removing the overlayer before depositing the fill can relax the step-coverage demands if it is desired that the fill (or a liner layer) make full contact with the sidewalls of the stem.

FIG. 3A shows a fill 308 in full contact with stem 302. FIG. 3B shows a liner layer 318 in full contact with stem 302, with fill 308 formed over liner layer 318. More than one liner layer can be used. The liner layer(s) can be functional (e.g. buffers or barriers) or used for the step coverage. FIG. 3C shows fill 308 with unfilled-corner voids 309, interface voids 319, or bulk voids 329 near stem 302, between the top of lower neighboring layer 101 and the bottom of an upper neighboring layer to be deposited later.

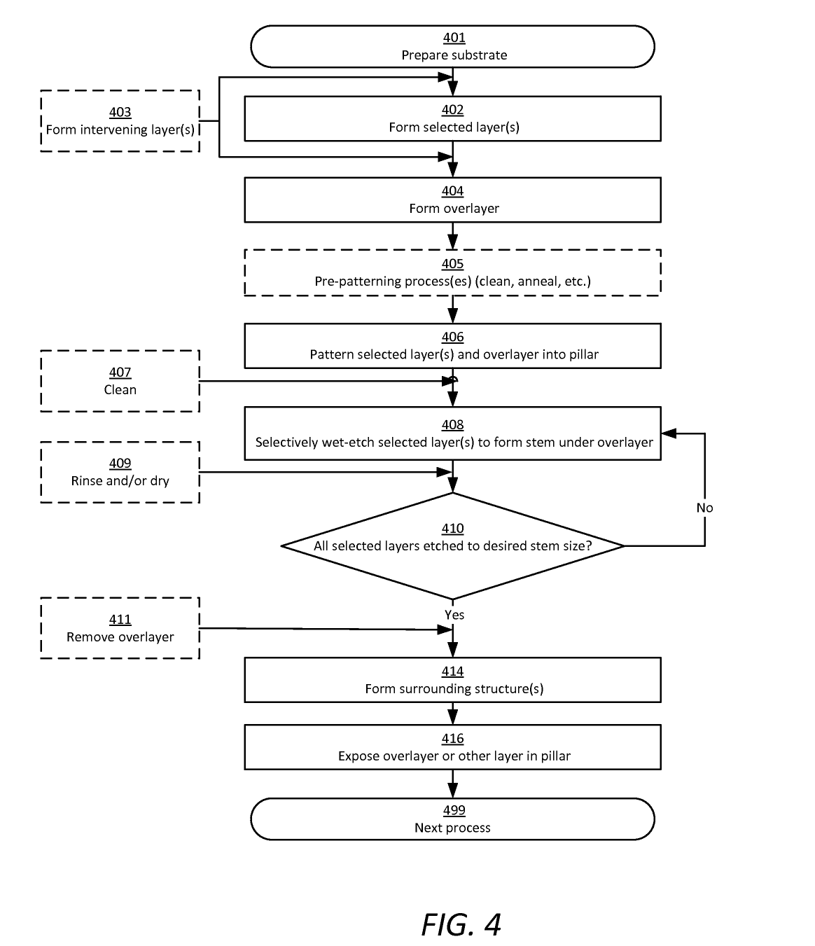

FIG. 4 is a flowchart of a process for forming pillars having one or more stem layers with reduced width. A substrate, which may include one or more existing layers or structures, is prepared 401. Optionally, some intervening layers may be formed 403. At least one selected layer, intended to become a narrowed stem, is formed 402. Optionally, more intervening layers may be formed 403. In some embodiments where there is more than one selected layer, intervening layers may be formed 403 between the selected layers. An overlayer is formed 404. Optionally, after forming the layers and before patterning the layers, some pre-patterning steps such as cleaning or annealing may be performed 405.

The overlayer, the selected layer(s), and optionally some of the intervening layers are patterned 406 into a pillar of initial lateral dimensions W_{1,x}×W_{1,z}. The patterning can be done by any suitable conventional method such as photolithography, shadow masking, laser scribing, etc. Initial lateral dimensions W_{1,x} and W_{1,z} are at or above the resolution limit of the patterning method; for instance, they may be >20 nm, >100 nm, or >1000 nm. Optionally, a clean 407 may follow initial patterning 406.

The next step is exposure to the selective wet etchant 408 to etch the sidewalls of the selected layers while maintaining the overlayer, substrate, and any intervening layers within acceptable tolerances for the device being built. Selective wet etching 408 removes a desired thickness D of material from the exposed sidewalls of at least one selected layer, so that the stem dimensions W_{2,x}=W_{1,x}−2D and W_{2,z}=W_{1,z}−2D. In some embodiments W_{2,x}, W₂,y, or both may be below the resolution limit of the patterning method used in step 406.

Meanwhile, the selective wet etchant removes a thickness less than D from non-selected layers, including the overlayer and the substrate. In some embodiments the selective wet etchant removes a thickness less than 25%, 10%, 5%, or 1% of D from non-selected layers. Optionally, the substrate can be rinsed and/or dried 409. If there is more than one selected layer, and one or more of the selected layers was not etched to the desired reduced width by the first selected etchant (condition 410 is not met), successive repetitions of step 408 (and optionally 409) may be executed with different selective wet etchants until all the selected layers are etched to the desired width and condition 410 is met.

Optionally, the overlayer may be removed 411 at this point with a wet or dry etchant compatible with the other layers, or alternatively it may be left in place. Surrounding structures, which may include the fill layer(s) or liner layer(s) shown in FIGS. 2A-3C, with or without intentional voids, or may include other structures. When either the overlayer or another layer in the pillar is re-exposed, the next process 499 may commence. Next process 499 may include forming a connection to the exposed layer of the pillar.

### Device Examples

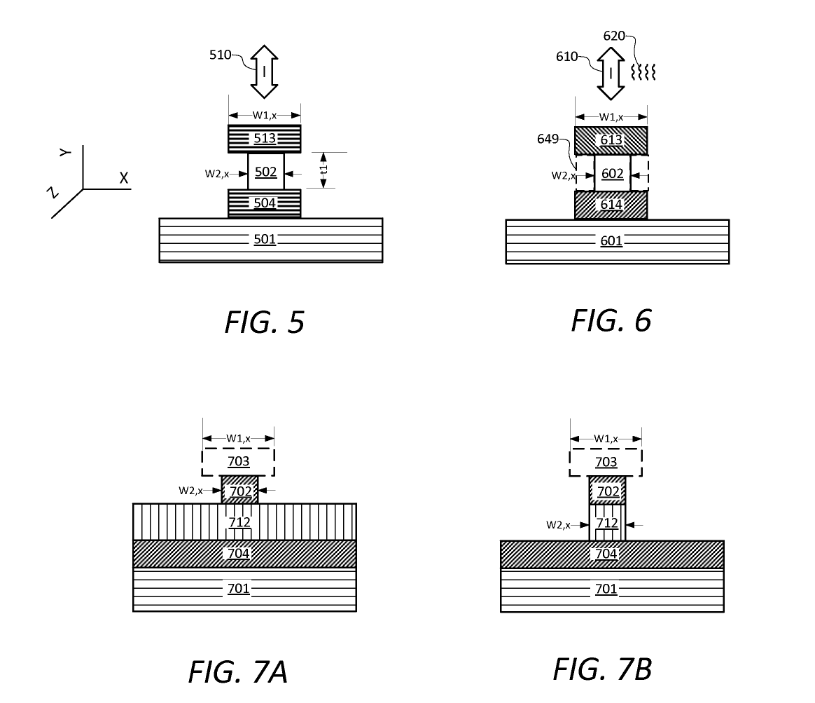

FIG. 5 conceptually illustrates a reduced-width series resistor in a device stack. A number of devices, including some non-volatile memory cells, use resistive layers to prevent excessive current from flowing through other connected components. The resistance of the resistive layer depends on intrinsic material resistivity, but also on the dimensions of the layer perpendicular to the current flow (smaller dimensions are associated with higher resistance). In the illustrated device, current will flow in the ±Y direction as indicated by arrow 510. Suppose resistive layer 502 is not resistive enough at the initially patterned area in the x-z plane of W_{1,x}×W_{1,z} (z-dimensions not shown in this view), and increasing its thickness t₁ is not an option.

To increase its resistance, it can be chosen as the selected layer in the method of FIG. 4 and thinned to a stem of smaller area W_{2,x}×W_{2,z} using a selected wet etchant that etches resistive layer 502 faster than it etches substrate 501, lower stack layers 504, or any upper stack layers 513 that were present during the wet etch step. One of the upper stack layers 513 may be the overlayer, or the overlayer may have been a sacrificial layer that was later removed. A dielectric fill, with or without voids, can then be formed over the substrate and stack, and a connection can be formed to connect the top layer of upper stack 513 with another component. In some embodiments, a conformal fill or liner layer near the resistor may be thermally conductive (e.g., a bismuth material) to keep the resistor from overheating. Materials for resistive layer 502 include ternary metal nitrides such as TaSiN, TaAlN, HfSiN, HfAlN, MoSiN, and MoAlN.

FIG. 6 conceptually illustrates a reduced-width switching layer in a non-volatile memory cell. Some types of non-volatile memory cells use switching layers that can be toggled between two stable values of an electrical property (e.g., resistance) by passing current through switching layer 602 in one or both directions 610 through electrodes 613 and 614. As used herein, “switching layer” means “a layer capable of being reversibly switched between at least two stable states by an applied electric or magnetic field.” Switching layer 602 may change its properties by changing some aspect of the bulk material: phase of the material, or the presence or absence of one or more internal conductive filaments (for example, of metal ions or oxygen vacancies). Materials for switching layers include silicon with diffused metal; silicon oxides, nitrides, and oxynitrides; high-k metal oxides such as HfOₓ, TaOₓ, TiOₓ, or ZrOₓ (the “x” may be a non-integer for non-stoichiometric compounds); perovskites; and phase-change materials such as chalcogenide glasses. Materials for electrodes include poly-silicon, metal nitrides, and metals. Other layers (e.g., barriers, buffers, and non-switching resistors) may also be present between the electrodes.

Some of the switching is responsive to electric field, some to heat 620 dissipated by current 610, and some may require both. The partially-conductive materials used in switching layers, however, tend to dissipate heat so that more current is needed to cause the layer to switch. Other layers (e.g., barriers, buffers, and non-switching resistors) may also be present between the electrodes.

In some non-volatile memory cells, less power is required for switching if the heat or field can be confined in a smaller volume. Filaments of ions or oxygen vacancies, for example, have been observed to be on the order of 1 nm wide. A reduction in transverse area from 20 nm×20 nm to 10 nm×10 nm would be expected to reduce the required operating power. Preferably, the reduced-width switching layer would be surrounded by a high-thermal-insulating material to confine the heat. In FIG. 6, switching layer 602 is chosen as the selected layer in the method of FIG. 4 and thinned to a stem of smaller area W_{2,x}×W_{2,z} using a selected wet etchant that etches switching layer 602 faster than it etches substrate 601, bottom electrode 614, top electrode 613 (which may be a different material than bottom electrode 614), or any other that were present during the wet etch step. For example, dilute HF would etch a hafnium oxide switching layer 40× faster than it would etch a tantalum-nitride electrode. A dielectric fill, with or without voids, can then be formed over the substrate and stack, and a connection can be formed to connect top electrode 613 with another component.

Some embodiments of non-volatile memory cells also include embedded resistors as illustrated in FIG. 5. Optionally, the embedded resistor can be a second selected layer, reduced in width by either the same selective wet etchant as is used for the switching layer or by a different selective wet etchant in a separate step.

FIGS. 7A-7B conceptually illustrate test structures with reduced effective width for screening candidate capacitor materials. Co-owned U.S. patent application Ser. No. 13/298,524, filed 17 Nov. 2011 and incorporated by reference herein in its entirety for all purposes, describes the screening of candidate materials and processes for capacitors by building test capacitor arrays with a common bottom electrode (for testing dielectric and top electrode candidates) or with both a common bottom electrode and a common dielectric layer (for testing top-electrode candidates). When candidate materials and processes are being screened for devices whose small size may affect the materials' physical behavior, it is advantageous to be able to test them “at-dimension” with an effective size similar to the intended device. When initially screening large numbers of materials, it is advantageous to produce the text structures simply and inexpensively.

In FIG. 7A, substrate 701 has a blanket-deposited bottom electrode 704, a blanket-deposited dielectric 712, and a patterned top electrode 702. For example, the screening process may involve comparing top electrodes 702 that differ in composition or method of formation from one part of substrate 701 to another. Each patterned electrode 702 forms an individual capacitor with dielectric 712 and bottom electrode 701, which can be tested to find the best-performing variation of top electrode 702.

In this example, the planned device size is smaller than the resolution limit of the initial patterning technique. Therefore, a sacrificial overlayer 703 was formed over electrode layer 702 prior to patterning, and electrode layer 702 was the selected layer in the method of FIG. 4. Overlayer 703 and electrode layer 702 were initially patterned into a pillar of width W_{1,x} larger than the intended device but above the resolution limit of the initial patterning technique. Then a selective wet etchant etched the sidewalls of electrode layer 702 to a planned device width W_{2,x}, followed by the removal of sacrificial overlayer 703. For example, dilute ammonia-peroxide or Standard Clean 1 would etch a tantalum-nitride electrode about 50× faster than it would etch a metal-oxide dielectric. Electrode layer 702 can now be tested “at-dimension.”

In FIG. 7B, substrate 701 has a blanket-deposited bottom electrode 704, a patterned dielectric 712, and a patterned top electrode 702. For example, the screening process may involve comparing top electrode/dielectric combinations that differ in composition or method of formation from one part of substrate 701 to another. Each patterned stack of electrode 702 and dielectric 712 forms an individual capacitor with bottom electrode 701, which can be tested to find the best-performing variation of top electrode 702.

In this example, the planned device size is smaller than the resolution limit of the initial patterning technique. Therefore, a sacrificial overlayer 703 was formed over electrode layer 702 prior to patterning, and electrode layer 702 and dielectric layer 703 were both selected layers in the method of FIG. 4. Overlayer 703, electrode layer 702, and dielectric layer 712 were initially patterned into a pillar of width W_{1,x} larger than the intended device but above the resolution limit of the initial patterning technique. Then a selective wet etchant etched the sidewalls of electrode layer 702 to a planned device width W_{2,x}, and either the same or a different selective wet etchant etched the sidewalls of dielectric layer 712 to a planned device width W_{2,x}, followed by the removal of sacrificial overlayer 703. The stack of electrode layer 702 and dielectric layer 712 can now be tested “at-dimension.”

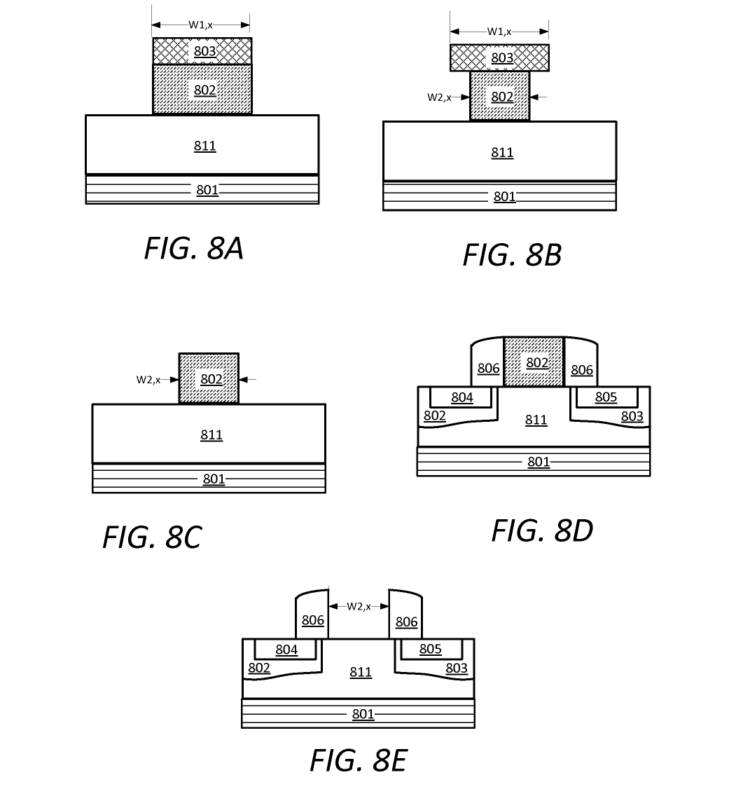

FIGS. 8A-8E conceptually illustrate a “gate-last” transistor fabrication with a reduced-width gate. Downscaling of transistors has benefited from the use of high-k materials, such as HfOx and ZrOx, as gate materials. However, these materials cannot withstand the anneal temperatures required for processing other structures in the device. The “gate-last” or “dummy-gate” approach builds the other structures around a sacrificial dummy gate, performs the anneal, then etches away the dummy gate and replaces it with the actual working materials. In this example, the goal is to make a gate with a width below the resolution of the initial patterning technique.

In FIG. 8A, substrate 801 has semiconductor layer 811, dummy gate layer 802, and overlayer 803. Dummy gate layer 802 and overlayer 803 have been patterned by the initial patterning technique into a pillar of width W_{1,x} wider than the intended gate but above the resolution limit of the initial patterning technique. Overlayer 803 may, in some embodiments, be a photoresist or etch-stop used in the initial patterning technique.

In FIG. 8B, a selective wet etchant etched the sidewalls of dummy gate layer 802 to a planned gate width W_{2,x}. In FIG. 8C, overlayer 803 is removed, for example by a different selective wet etch such as a photoresist strip (e.g., an SPM mixture of sulfuric acid and hydrogen peroxide). Reduced-width dummy gate 802 is now ready for use. In FIG. 8D, transistor structures such as channel 811, source 802, source contact 804, drain 803, drain contact 805, and spacers 806 are built around dummy gate 802. The structures are annealed with the temperature-tolerant dummy gate in place. Finally, in FIG. 8E, dummy gate 802 is etched away and a high-k metal gate of reduced width W_{2,x} can replace it. Depending on the nature of the surrounding structures, the same selective wet etchant used to narrow the dummy gate in FIG. 8B may be used to completely remove it in FIG. 8E. Alternatively, a different etchant may be used.

If suitable selective wet etchants are available, the same technique can be used in a “gate-first” fabrication, with selected layer 802 being the actual, anneal-tolerant gate.

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

1. A method of fabricating a semiconductor device, the method comprising:
forming a first layer on a substrate;
forming an overlayer over the first layer;
patterning the overlayer and the first layer to form a pillar; and
exposing the pillar to a first wet etchant;
wherein the first wet etchant is a phosphoric acid solution;
wherein the first wet etchant etches the first layer faster than the first wet etchant etches the overlayer; and
wherein the pillar is exposed to the first wet etchant, until the first layer forms a stem of a first width.

2. The method of claim 1, wherein the first width is less than a resolution limit of the patterning.

3. The method of claim 1, wherein the patterning comprises photolithography.

4. The method of claim 1, wherein an unselected layer on the substrate loses less than 10% of its thickness or width after exposure to the first wet etchant.

5. The method of claim 4, wherein the unselected layer comprises the overlayer.

6. The method of claim 1, further comprising:
forming a second layer above the substrate prior to forming the overlayer over the first layer,
wherein the overlayer is formed over the second layer, and
wherein the pillar comprises the second layer; and
etching a sidewall of the second layer to a second width.

7. The method of claim 6, wherein etching the sidewall of the second layer to the second width further comprises etching the sidewall of the second layer to at least a portion of the second width by the first wet etchant.

8. The method of claim 6, wherein etching the sidewall of the second layer to the second width is done by the first wet etchant, and
wherein the second layer is etched to the second width at the same time the first layer is etched to the first width by the first wet etchant.

9. The method of claim 6, wherein the sidewall of the second layer is etched to the second width at least partially by a second wet etchant.

10. The method of claim 1, wherein the first layer is a conductive layer.

11. The method of claim 1, wherein the first layer is a dielectric layer.

12. The method of claim 1, wherein the first layer is a semiconducting layer.

13. The method of claim 1, wherein the first layer has a switchable electric property.

14. The method of claim 13, wherein the switchable electric property is resistance.

15. The method of claim 1, further comprising forming a third layer over the pillar after the first layer forms the stem of the first width.

16. The method of claim 15, wherein the third layer conformally contacts sidewalls of the stem.

17. The method of claim 15, further comprising forming a fourth layer over the pillar before forming the third layer, wherein the fourth layer conformally contacts sidewalls of the stem.

18. The method of claim 15, wherein the third layer comprises at least one void between the bottom of an upper neighboring layer and the top of a lower neighboring layer;
wherein the upper neighboring layer is above the first layer and the lower neighboring layer is below the first layer.

19. The method of claim 1, further comprising removing the overlayer.

20. The method of claim 19, wherein the overlayer is removed before depositing an additional layer over the pillar.
